(19) United States
(12) Patent Application Publication
(10) Pub. No.: US 2025/0151357 A1
(43) Pub. Date: May 8, 2025

(54) SEMICONDUCTOR FABRICATION PROCESSES FOR DEFECT REDUCTION

(71) Applicant: Taiwan Semiconductor Manufacturing Company, Ltd., Hsinchu (TW)

(72) Inventors: Bo-Yu Lai, Taipei City (TW); Chung-I Yang, Hsinchu City (TW); Wei-Yang Lee, Taipei City (TW); Chih-Ching Wang, Kinmen County (TW)

(21) Appl. No.: 18/504,398

(22) Filed: Nov. 8, 2023

(51) Int. Cl. H01L 29/66; H01L 21/8234; H01L 27/088; H01L 29/06; H01L 29/08; H01L 29/423; H01L 29/775; H01L 29/786

(52) U.S. Cl. CPC H10D 64/017; H10D 30/014; H10D 30/43; H10D 30/6735; H10D 30/6757; H10D 62/121; H10D 62/151; H10D 84/0128; H10D 84/013; H10D 84/038; H10D 84/83

(57) ABSTRACT

Semiconductor structures and methods for forming the same are provided. A semiconductor structure according to the present disclosure includes a substrate, a first base fin and a second base fin rising from the substrate, an isolation feature disposed over the substrate and between the first base fin and the second base fin, a first bottom epitaxial feature over the first base fin, a second bottom epitaxial feature over the second base fin, an isolation layer on the first bottom epitaxial feature, a first source/drain feature over the isolation layer, a second source/drain feature disposed over and in contact with the second bottom epitaxial feature, a contact etch stop layer (CESL) over the first source/drain feature and the isolation feature, a first interlayer dielectric (ILD) layer over the CESL, and a second ILD layer over and in direct contact with the second source/drain feature.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate devices have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and Gate-all-around (GAA) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A GAA transistor has a gate structure that can extend, partially or fully, around a channel region to provide access to the channel region on two or more sides. Because its gate structure surrounds the channel regions, a GAA transistor may also be referred to as a surrounding gate transistor (SGT). Because the channel region of an GAA transistor may include nanowires or nanosheets and its configuration resembles a bridge, a GAA transistor may also be referred to a multi-bridge-channel (MBC) transistor, a nanowire transistor, or a nanosheet transistor.

Multi-gate devices may be fabricated using a gate-first process or a gate-last process. The former forms a high-k metal gate structure or portions thereof before going source/drain features. The latter forms a dummy gate stack as a placeholder during the formation of the source/drain features and relaces the dummy gate stack with a high-k metal gate structure.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flow chart of a method for forming a semiconductor device, according to one or more aspects of the present disclosure.

FIGS. 2-27 illustrate fragmentary cross-sectional views of a workpiece undergoing a fabrication process according to the method of FIG. 1, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

During the development of high-k metal gate technology, both gate-first processes and gate-last processes have been proposed. Gate-first processes form high-k dielectric layers or metal gate structures before formation of source/drain features. In a gate-last process, dummy gate stacks are first formed over channel regions of active regions as placeholders when source/drain features are formed. These dummy gate stacks are subsequently removed and replaced with high-k metal gate structures. Because the gate-last processes prevent the high-k metal gate structure from going through high thermal processes, they are known to provide good thermal stability for the high-k dielectric layers and reduced threshold voltage shifting. When gate-last processes are used to form p-type GAA transistors, there are several challenges. For example, in some situations, the process to release channel layers as suspended channel members may cause damages to p-type source/drain features. In some situations, p-type source/drain features may not strain the channel region enough before the channel members are released from sacrificial layers.

The present disclosure provides a method of forming a semiconductor device with improved p-type device performance. The method of the present disclosure forms n-type source/drain features before formation of a gate structure of a GAA transistor and p-type source/drain features after formation of the gate structure. By forming the p-type source/drain features last, the p-type source/drain features are less prone to defects and are likely to effectively strain the channel regions.

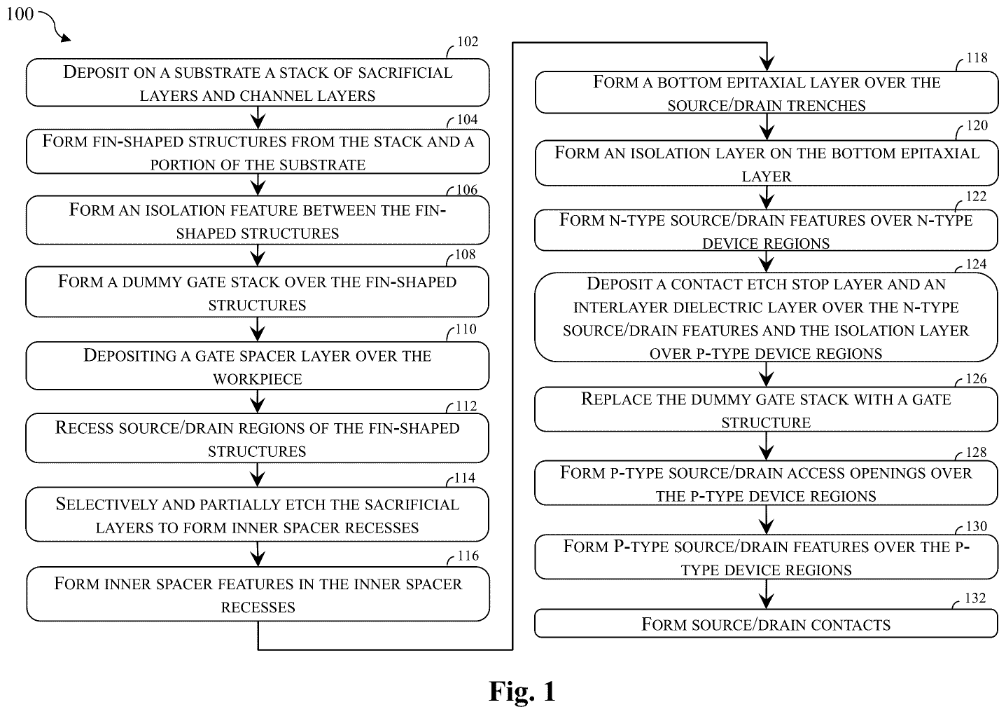

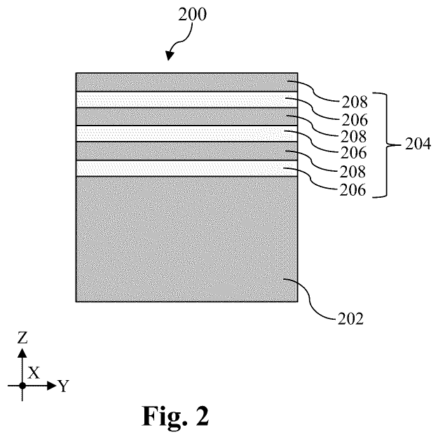

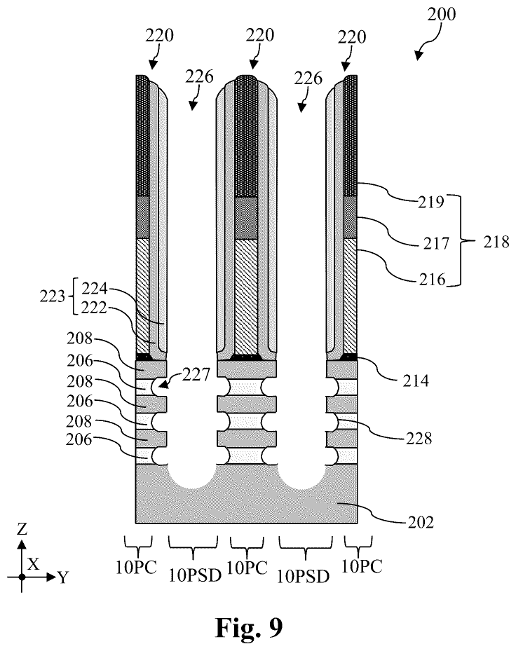

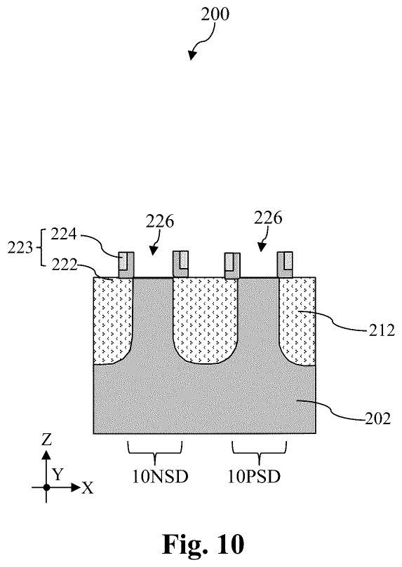

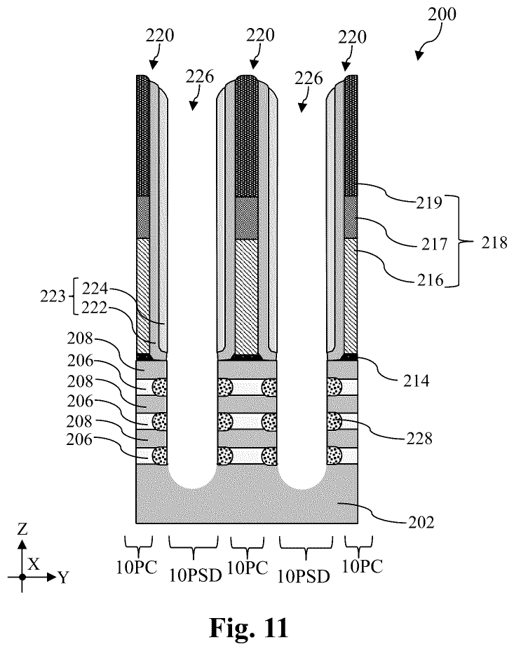

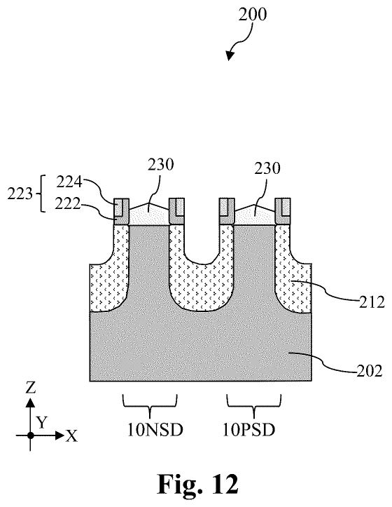

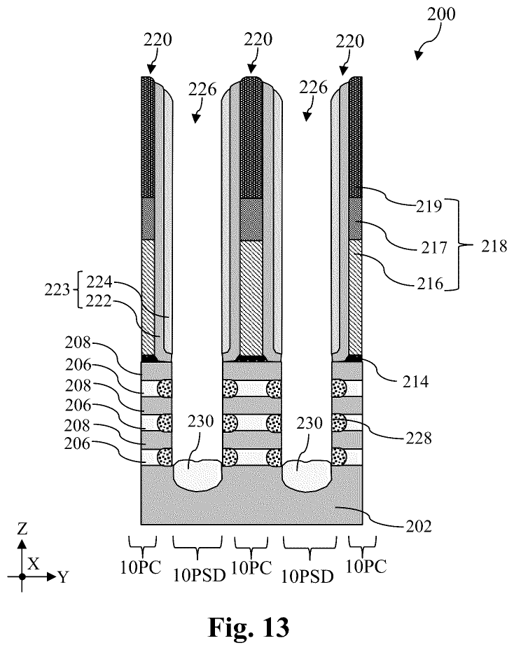

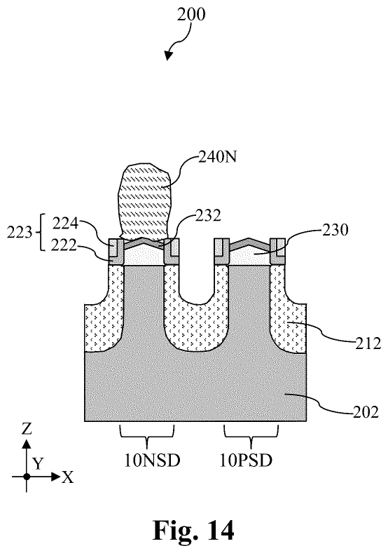

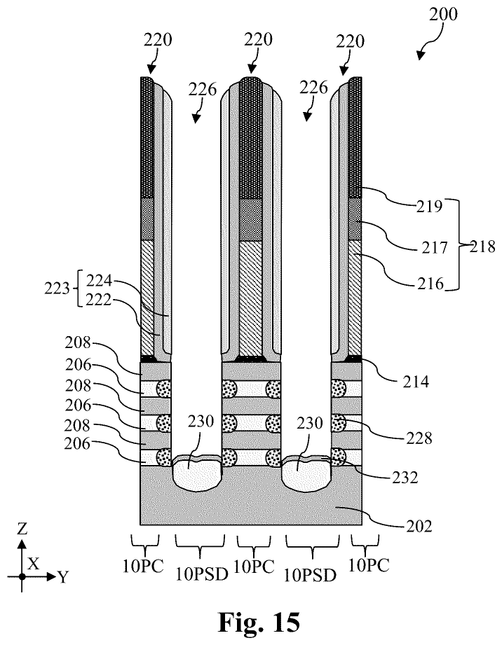

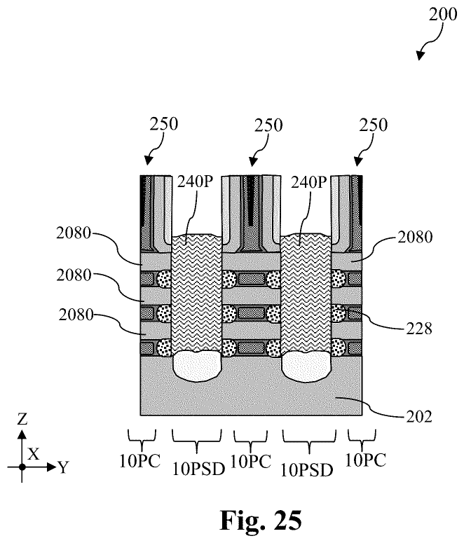

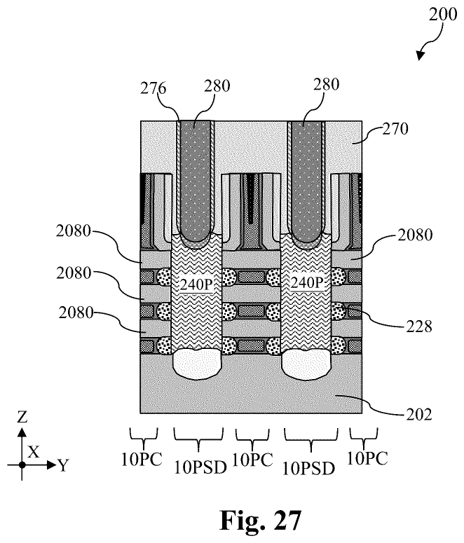

The various aspects of the present disclosure will now be described in more detail with reference to the figures. In that regard, FIG. 1 is a flowchart illustrating method 100 of forming a semiconductor device from a workpiece according to embodiments of the present disclosure. Method 100 is merely an example and is not intended to limit the present disclosure to what is explicitly illustrated in method 100. Additional steps can be provided before, during and after method 100, and some steps described can be replaced, eliminated, or moved around for additional embodiments of method 100. Not all steps are described herein in detail for reasons of simplicity. Method 100 is described below in conjunction with FIGS. 2-27, which are fragmentary cross-sectional views of the semiconductor device at different stages of fabrication according to embodiments of method 100. Because the workpiece 200 will be fabricated into a semiconductor structure or a semiconductor device, the workpiece 200 may be referred to herein as a semiconductor device 200 or a semiconductor structure 200 as the context requires. For avoidance of doubts, the X, Y and Z directions in FIGS. 2-27 are perpendicular to one another. Throughout the present disclosure, like reference numerals denote like features, unless otherwise excepted. Furthermore, as used herein, source/drain region(s) or source/drain feature(s) may refer to a source or a drain, individually or collectively, dependent upon the context.

Referring to FIGS. 1 and 2, method 100 includes a block 102 where a stack 204 of sacrificial layers 206 and channel layers 208 is deposited on a substrate 202. As shown in FIG. 2, the workpiece 200 includes a substrate 202. In some embodiments, the substrate 202 may be a semiconductor substrate such as a silicon (Si) substrate. The substrate 202 may include various doping configurations depending on design requirements as is known in the art. In embodiments where the semiconductor device is p-type, an n-type doping profile (i.e., an n-type well or n-well) may be formed on the substrate 202. In some implementations, the n-type dopant for forming the n-type well may include phosphorus (P) or arsenide (As). In embodiments where the semiconductor device is n-type, a p-type doping profile (i.e., a p-type well or p-well) may be formed on the substrate 202. In some implementations, the n-type dopant for forming the p-type well may include boron (B). The suitable doping may be performed using ion implantation of dopants and/or diffusion processes. The substrate 202 may also include other semiconductors such as germanium (SiGe), silicon carbide (SiC), silicon germanium (SiGe), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features.

In some embodiments, the stack 204 includes sacrificial layers 206 of a first semiconductor composition interleaved by channel layers 208 of a second semiconductor composition. The first and second semiconductor composition may be different. In some embodiments, the sacrificial layers 206 include silicon germanium (SiGe) and the channel layers 208 include silicon (Si). It is noted that three (3) layers of the sacrificial layers 206 and three (3) layers of the channel layers 208 are alternately arranged as illustrated in FIG. 2, which is for illustrative purposes only and not intended to be limiting beyond what is specifically recited in the claims. It can be appreciated that any number of epitaxial layers may be formed in the stack 204. The number of layers depends on the desired number of channels members for the semiconductor device 200. In some embodiments, the number of channel layers 208 is between 2 and 10.

In some embodiments, all sacrificial layers 206 may have a substantially uniform first thickness and all of the channel layers 208 may have a substantially uniform second thickness. The first thickness and the second thickness may be identical or different. As described in more detail below, the channel layers 208 or parts thereof may serve as channel member(s) for a subsequently-formed multi-gate device and the thickness of each of the channel layers 208 is chosen based on device performance considerations. The sacrificial layers 206 in channel regions(s) may eventually be removed and serve to define a vertical distance (along the Z direction) between adjacent channel region(s) for a subsequently-formed multi-gate device and the thickness of each of the sacrificial layers 206 is chosen based on device performance considerations.

The layers in the stack 204 may be deposited using a molecular beam epitaxy (MBE) process, a vapor phase deposition (VPE) process, and/or other suitable epitaxial growth processes. As stated above, in at least some examples, the sacrificial layers 206 include an epitaxially grown silicon germanium (SiGe) layer and the channel layers 208 include an epitaxially grown silicon (Si) layer. In some embodiments, the sacrificial layers 206 and the channel layers 208 are substantially dopant-free (i.e., having an extrinsic dopant concentration from about 0 cm⁻³ to about 1×10¹⁷ cm⁻³), where for example, no intentional doping is performed during the epitaxial growth processes for the stack 204.

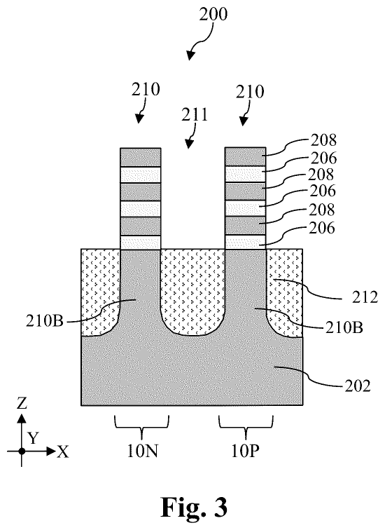

Referring still to FIGS. 1 and 3, method 100 includes a block 104 where a fin-shaped structure 210 is formed from the stack 204 and a portion of the substrate 202. To pattern the stack 204, a hard mask layer (not explicitly shown in figures) may be deposited over the stack 204 to form an etch mask. The hard mask layer may be a single layer or a multi-layer. For example, the hard mask layer may include a pad oxide layer and a pad nitride layer over the pad oxide layer. The fin-shaped structure 210 may be patterned from the stack 204 and a portion of the substrate 202 using a lithography process and an etch process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., RIE etching), wet etching, and/or other etching methods. As shown in FIG. 3, the etch process at block 104 forms trenches 211 extending through the stack 204 and a portion of the substrate 202. The trenches 211 define the fin-shaped structures 210. Besides the portions formed from the stack 204, each of the fin-shaped structures 210 includes a base fin 210B extending from the substrate 202. In some implementations, double-patterning or multi-patterning processes may be used to define fin-shaped structures 210 that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shaped structure 210 by etching the stack 204 and a portion of the substrate 202. As shown in FIG. 3, the fin-shaped structure 210 extends vertically along the Z direction and lengthwise along the X direction.

Referring to FIGS. 1 and 3, method 100 includes a block 106 where an isolation feature 212 is formed between the fin-shaped structures 210. In some embodiments, the isolation feature 212 may be deposited in trenches 211 between neighboring fin-shaped structures 210 to isolate them from one another. The isolation feature 212 may also be referred to as a shallow trench isolation (STI) feature 212. By way of example, in some embodiments, a dielectric material is first deposited over the substrate 202, filling the trenches 211 with the dielectric material. In some embodiments, the dielectric material may include silicon oxide, silicon nitride, silicon oxynitride, fluorine-doped silicate glass (FSG), a low-k dielectric, combinations thereof, and/or other suitable materials. In various examples, the dielectric layer may be deposited by a spin-on coating process, a CVD process, a subatmospheric CVD (SACVD) process, a flowable CVD (FCVD) process, an ALD process, a physical vapor deposition (PVD) process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the STI features 212. The fin-shaped structures 210 rise above the STI features 212 after the recessing.

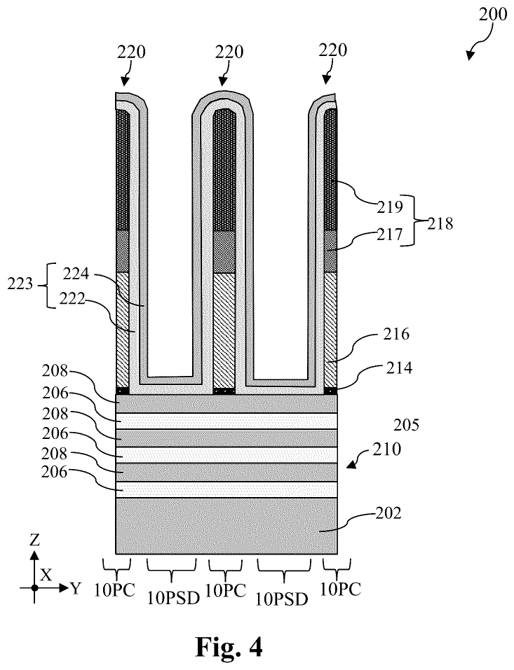

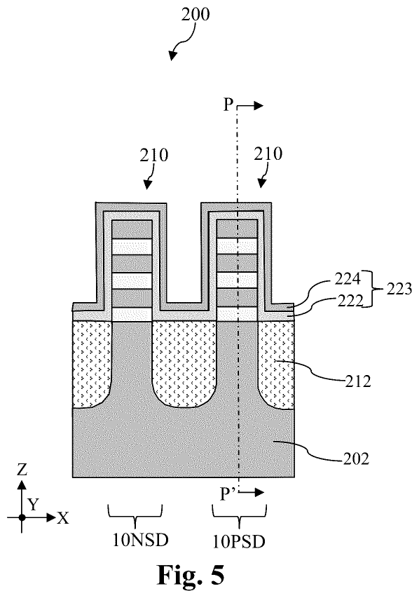

Referring to FIGS. 1, 4 and 5, method 100 includes a block 108 where a dummy gate stack 220 is formed over the fin-shaped structures 210. FIG. 4 illustrates a fragmentary cross-sectional view along a lengthwise direction (i.e., Y direction) of a p-type fin-shaped structure, which includes p-type channel regions 10PC and p-type source/drain regions 10PSD. FIG. 5 illustrates a fragmentary cross-sectional view along a lengthwise direction (i.e., X direction) of the dummy gate stack 220. FIG. 4 may be regarded as a cross-sectional view along cross-section P-P′ shown in FIG. 5. A fragmentary cross-sectional view along a lengthwise direction of an n-type fin-shaped structure is omitted for simplicity.

In some embodiments represented in FIG. 4, the dummy gate stack 220 includes a dummy dielectric layer 214 and a dummy electrode layer 216. In those embodiments, a gate-top hard mask layer 218 that is used to pattern the dummy gate stack 220 may remain on top of the dummy electrode layer 216 to protect the dummy electrode layer 216. In the depicted embodiments, the gate-top hard mask layer 218 may be include a nitride hard mask layer 217 and an oxide hard mask layer 219 over the nitride hard mask layer 217. In some implementations, the dummy dielectric layer 214 may include silicon oxide, the dummy electrode layer 216 may include polysilicon, the nitride hard mask layer 217 may include silicon nitride or silicon oxynitride, and the oxide hard mask layer 219 may include silicon oxide. For ease of reference, the dummy gate stack 220 may be used to refer to not only the dummy dielectric layer 214, the dummy electrode layer 216, but also the gate-top hard mask layer 218 (including the nitride hard mask layer 217 and the oxide hard mask layer 219). The dummy gate stack 220 serves as a placeholder to undergo various processes and is to be removed and replaced by the functional gate structure at a later step. As shown in FIG. 4, the dummy gate stacks 220 are disposed over channel regions (p-type channel regions 10PC shown in FIG. 4) of the fin-shaped structure 210. As shown in FIGS. 4 and 5, the source/drain regions, including the p-type source/drain regions 10PSD and the n-type source/drain regions 10NSD, are not covered by the dummy gate stacks 220. Each of the p-type channel regions 10PC is disposed between two p-type source/drain regions 10PSD along the lengthwise direction of the fin-shaped structure 210, which is aligned with the Y direction. Each of the dummy dielectric layer 214, the dummy electrode layer 216, and the gate-top hard mask layer 218 may be deposited using a CVD process, an ALD process, or a suitable deposition process. Similar to the fin-shaped structures 210, the dummy gate stacks 220 may be patterned using photolithography and etch processes.

Referring to FIGS. 1, 4 and 5, method 100 includes a block 110 where a gate spacer layer 223 is deposited over the workpiece 200. The gate spacer layer 223 may be a single layer or a multi-layer. FIGS. 4 and 5 illustrate an example of a multi-layer where the gate spacer layer 223 includes a first spacer layer 222 and a second spacer layer 224. The first spacer layer 222 and the second spacer layer 224 are deposited conformally over the workpiece 200, including over top surfaces and sidewalls of the dummy gate stack 220. The term “conformally” may be used herein for ease of description of a layer having substantially uniform thickness over various regions. The first spacer layer 222 may have a lower dielectric constant than the second spacer layer 224 and the second spacer layer 224 etch more slowly than the first spacer layer 222. In some embodiments, the first spacer layer 222 may include silicon oxide, silicon oxycarbide, silicon nitride, or silicon oxycarbonitride. The second spacer layer 224 may include silicon nitride, silicon oxycarbide, or silicon oxycarbonitride, aluminum oxide, or a suitable dielectric material. When both the first spacer layer 222 and the second spacer layer 224 include silicon oxycarbide or silicon oxycarbonitride, a carbon content of the second spacer layer 224 is greater than a carbon content of the first spacer layer 222 to be more etch resistant. The first spacer layer 222 and the second spacer layer 224 may be deposited over the dummy gate stack 220 using processes such as, CVD process, a subatmospheric CVD (SACVD) process, a flowable CVD (FCVD) process, an ALD process, a PVD process, or other suitable process. As shown in FIGS. 4 and 5, the gate spacer layer 223 is not only disposed over sidewalls and top surfaces of the dummy gate stacks 220 in p-type channel regions 10PC and n-type channel regions (not explicitly shown) but also over sidewalls and top surfaces of the fin-shaped structures 210 in the n-type source/drain regions 10NSD and p-type source/drain regions 10PSD.

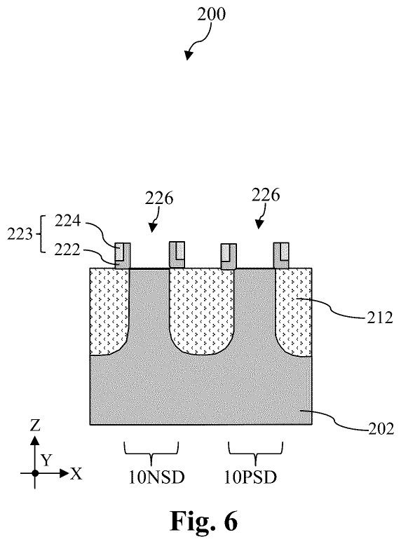

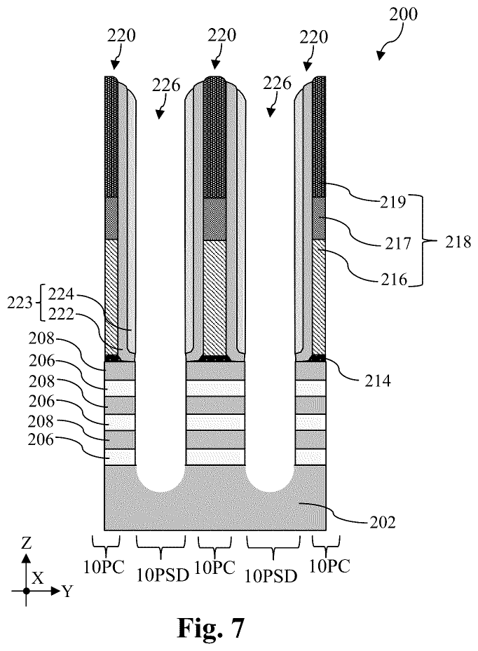

Referring to FIGS. 1, 6 and 7, method 100 includes a block 112 where source/drain regions of the fin-shaped structures 210 are recessed. While not explicitly shown, a photolithography process and at least one hard mask may be used to perform operations at block 112. At block 112, the n-type source/drain regions 10NSD and p-type source/drain regions 10PSD of the fin-shaped structures 210 that are not covered by the dummy gate stack 220 and the gate spacer layer 223 are etched by a dry etch or a suitable etching process to form the source/drain recesses 226 (or source/drain trenches 226). For example, the dry etch process may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. In some embodiments represented in FIGS. 6 and 7, the n-type source/drain regions 10NSD and p-type source/drain regions 10PSD are recessed to expose sidewalls of the sacrificial layers 206 and the channel layers 208 in the source/drain recesses 226. As shown in FIG. 7, the recess at block 112 may continue downward to extend into a portion of the substrate 202.

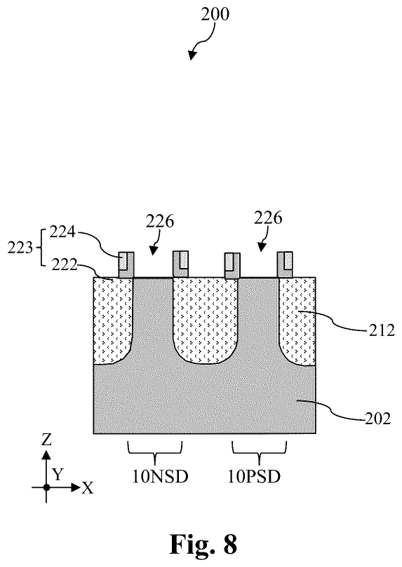

Referring to FIGS. 1, 8 and 9, method 100 includes a block 114 where the sacrificial layers 206 are selectively and partially etched to form inner spacer recesses 227. At block 114, the sacrificial layers 206 exposed in the source/drain recesses 226 are selectively and partially recessed along the Y direction to form inner spacer recesses 227 while the gate spacer layer 223 and the channel layers 208 are substantially unetched. In embodiment where the channel layers 208 consist essentially of Si and sacrificial layers 206 consist essentially of SiGe, the selective recess of the sacrificial layers 206 may include a SiGe oxidation process followed by a SiGe oxide removal. In those embodiments, the SiGe oxidation process may include use of ozone. In some embodiments, the selective recess may be a selective isotropic etching process (e.g., a selective dry etching process or a selective wet etching process), and the extent the sacrificial layers 206 are recessed is controlled by duration of the etching process. In some embodiments, the selective dry etching process may include use of one or more fluorine-based etchants, such as fluorine gas or hydrofluorocarbons. In some embodiments, the selective wet etching process may include a hydro fluoride (HF) or ammonium hydroxide (NH₄OH) etchant. Structures shown in FIG. 8 may not undergo any changes at block 114.

Referring to FIGS. 1, 10 and 11, method 100 includes a block 116 where inner spacer features 228 are formed in the inner spacer recesses 227. In some embodiments, operations at block 116 may include blanket deposition of an inner spacer material layer over the workpiece 200 and an etch-back of the inner spacer material layer to form the inner spacer features 228. The inner spacer material layer may be a single layer or a multilayer. In some implementations, the inner spacer material layer may be deposited using CVD, PECVD, LPCVD, ALD or other suitable method. The inner spacer material layer may include metal oxides, silicon oxide, silicon oxycarbonitride, silicon nitride, silicon oxynitride, carbon-rich silicon carbonitride, or a low-k dielectric material. The metal oxides here may include aluminum oxide, zirconium oxide, tantalum oxide, yttrium oxide, titanium oxide, lanthanum oxide, or other suitable metal oxide.

The deposited inner spacer material layer is then etched back to remove the inner spacer material layer from the sidewalls of the channel layers 208 to obtain the inner spacer features 228 in the inner spacer recesses 227. At block 116, the inner spacer material layer may also be removed from the top surfaces of dummy gate stack 220, the gate spacer layer 223, and the isolation features 212. In some embodiments, the composition of the inner spacer material layer is selected such that the inner spacer material layer may be selectively removed without substantially etching the gate spacer layer 223. In some implementations, the etch back operations performed at block 116 may include use of hydrogen fluoride (HF), fluorine gas (F₂), hydrogen (H₂), ammonia (NH₃), nitrogen trifluoride (NF₃), or other fluorine-based etchants.

Referring to FIGS. 1, 12 and 13, method 100 includes a block 118 where a bottom epitaxial layer 230 is formed over the source/drain trenches 226. The bottom epitaxial layer 230 may include an undoped semiconductor material, such as undoped silicon (Si), undoped germanium (Ge), or undoped silicon germanium (SiGe). In one embodiment, the bottom epitaxial layer 230 includes undoped silicon (Si). The bottom epitaxial layer 230 may be epitaxially formed from the exposed top surfaces of the substrate 202 in the n-type source/drain regions 10NSD and p-type source/drain regions 10PSD using process conditions more conducive to epitaxial growth on the top-face crystalline surfaces. Suitable epitaxial processes for block 118 may include an MBE process, a VPE process, an UHV-CVD process, an MOCVD process, and/or other suitable epitaxial growth processes. Due to the crystalline orientation, the bottom epitaxial layer 230 deposited on sidewalls of the channel layers 208 includes more crystalline defects, which allow selective removal of the bottom epitaxial layer 230 deposited on the sidewalls of the channel layers 208 in a subsequent etch back process. The bottom epitaxial layer 230 deposited on the exposed substrate 202 is less defective and can withstand the etching process when the more defective bottom epitaxial layer 230 on sidewalls of the channel layers 208 is removed.

Referring to FIGS. 1, 14 and 15, method 100 includes a block 120 where an isolation layer 232 is formed on the bottom epitaxial layer 230. In some embodiments, in order to prevent or reduce leakage from n-type source/drain features to the substrate 202, the isolation layer 232 is deposited on the bottom epitaxial layer 230. In an example process, the isolation layer 232 is directionally/anisotropically deposited over the workpiece 200 such that the isolation layer 232 on top-facing surfaces is thicker than on sidewalls. Then an isotropic etch back process is performed to remove the thinner isolation layer 232 on the sidewall, leaving behind the isolation layer 232 on the bottom epitaxial layer 230. The isolation layer 232 may include silicon nitride, silicon oxide, silicon oxynitride, silicon carbide, or silicon oxycarbonitride. In one embodiment, the isolation layer 232 includes silicon nitride. In some implementations, the isolation layer 232 may be deposited using CVD or plasma enhanced CVD (PECVD).

Referring to FIGS. 1, 14 and 15, method 100 includes a block 122 where n-type source/drain features 240N are formed over n-type source/drain regions 10NSD. While not explicitly shown in the figures, a masking layer, such as a bottom antireflective coating (BARC) layer may be deposited over the workpiece 200 to cover the p-type active regions, including the p-type source/drain regions 10PSD while the n-type source/drain regions 10NSD remain exposed. At block 122, the n-type source/drain features 240N are formed over the n-type source/drain regions 10NSD by epitaxially and selectively depositing one or more epitaxial layers on exposed sidewalls of the channel layers 208. The one or more epitaxial layers in the n-type source/drain feature 240N may include silicon (Si) and are in-situ doped with an n-type dopant, such as phosphorus (P) or arsenic (As). When there are multiple epitaxial layer in the n-type source/drain feature 240N, epitaxial layers closer to the sidewalls of the channel layers 208 include smaller n-type dopant concentrations than epitaxial layers farther away from the sidewalls of the channel layers 208. Suitable epitaxial deposition processes to deposit the n-type source/drain features 240N may include an MBE process, a VPE process, an UHV-CVD process, an MOCVD process. In some embodiments, in order to ensure quality of the n-type source/drain features 240N, a process temperature for depositing the n-type source/drain features 240N may be between 500° C. and about 750° C. To activate the dopants in the n-type source/drain features 240N, block 122 may include an anneal process to anneal the n-type source/drain features 240N. In some implementation, the anneal process may include a rapid thermal anneal (RTA) process, a laser spike anneal process, a flash anneal process, or a furnace anneal process. In some instances, the anneal process includes a peak anneal temperature between about 900° C. and about 1100° C. After formation of the n-type source/drain features 240N, the masking layer (e.g., a BARC layer) is removed by ashing.

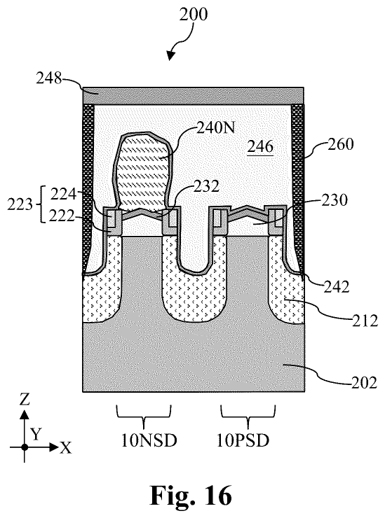

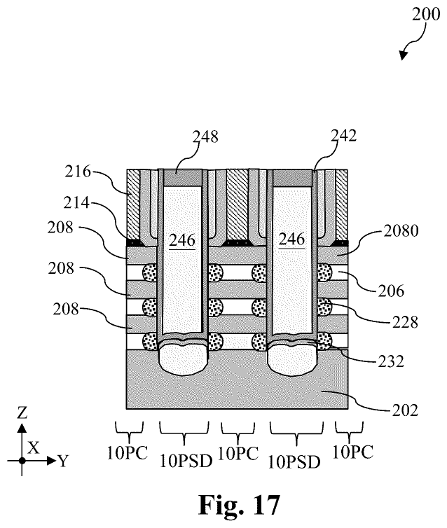

Referring to FIGS. 1, 16 and 17, method 100 includes a block 124 where a contact etch stop layer 242 and an interlayer dielectric (ILD) layer 246 are deposited over the n-type source/drain features 240N and the isolation layer 232 over the p-type source/drain regions 10PSD. Operations at block 124 may include formation of an contact etch stop layer (CESL) 242, deposition of an interlayer dielectric (ILD) layer 246 over the CESL 242, a planarization process to remove excess ILD layer material, etching back of the ILD layer 246, formation of a self-alignment capping (SAC) layer 248, and a planarization process to expose the dummy electrode layer 216. As shown in FIGS. 16 and 17, the CESL 242 is formed prior to forming the ILD layer 246. In some examples, the CESL 242 may include silicon nitride, silicon oxynitride, or a combination thereof. The CESL 242 may be formed by ALD, plasma-enhanced chemical vapor deposition (PECVD) process and/or other suitable deposition or oxidation processes. The ILD layer 246 is then deposited over the CESL 242. In some embodiments, the ILD layer 246 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 246 may be deposited by flowable CVD (FCVD), spin-on coating, PECVD process, or other suitable deposition technique. In some embodiments, after formation of the ILD layer 246, the workpiece 200 may be annealed to improve integrity of the ILD layer 246.

After the deposition of the ILD layer 246, a planarization process, such as a chemical mechanical polishing (CMP) process is performed to remove excess ILD layer material and provide a planar top surface. After the planarization process, the ILD layer 246 is selectively etched back using wet etching process that is selective to silicon oxide. For example, the wet etching process may include dilute hydrogen fluoride (DHF) solution or a buffered oxide etch (BOE) process that uses dilute hydrogen fluoride and ammonium fluoride (NH₄F). After the ILD layer 246 is recessed, the SAC layer 248 is deposited over the recessed ILD layer 246. In some embodiments, the SAC layer 248 may include silicon nitride, silicon oxycarbonitride, or silicon oxynitride. A planarization process is performed to removed excess SAC layer 248. In some embodiments represented in FIGS. 16 and 17, before the formation of the SAC layer 248, a cut dummy gate process is performed to form a cut dummy gate trench through the dummy gate stack 220, the ILD layer 246 and maybe a portion of the CESL 242. A dielectric material, such as silicon nitride, aluminum oxide, hafnium oxide, is deposited to form the cut dummy gate trench to form gate cut features 260. As shown in FIG. 16, each of the gate cut features 260 may partially extend into the isolation feature 212.

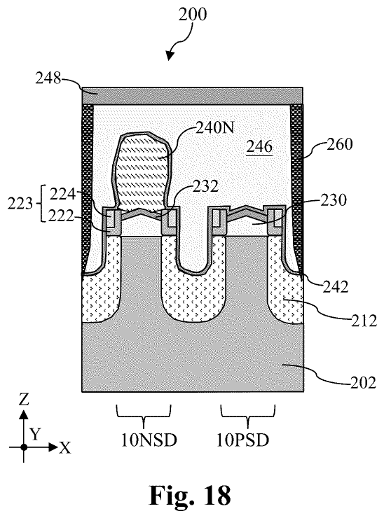

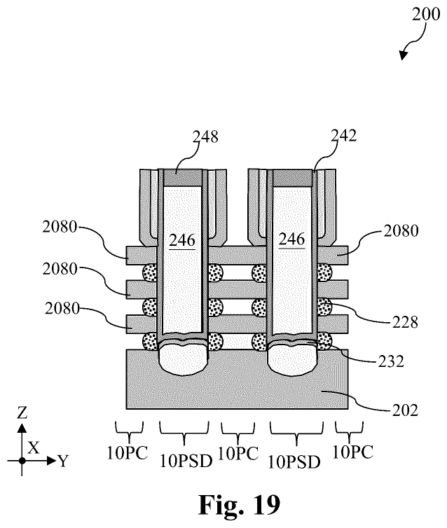

Referring to FIGS. 1, 18, 19, 20, and 21, method 100 includes a block 126 where the dummy gate stack 220 is replaced with a gate structure 250. As shown in FIG. 19, the dummy electrode layer 216 exposed at block 124 is then selectively removed, followed up by selective removal of the dummy dielectric layer 214. The removal of the dummy electrode layer 216 and the dummy dielectric layer 214 may include one or more etching processes that are selective to the material in the dummy electrode layer 216 and the dummy dielectric layer 214. For example, the removal of the dummy electrode layer 216 and the dummy dielectric layer 214 may be performed using as a selective wet etch, a selective dry etch, or a combination thereof that is selective to the dummy electrode layer 216 and the dummy dielectric layer 214. After the removal of the dummy electrode layer 216 and the dummy dielectric layer 214, surfaces of the channel layers 208 and the sacrificial layers 206 in the channel regions are exposed in the gate trench. Then the sacrificial layers 206 in the channel regions are selectively removed to release the channel layers 208 as channel members 2080. The selective removal of the sacrificial layers 206 may be implemented by selective dry etch, selective wet etch, or other selective etch processes. In some embodiments, the selective wet etching includes an APM etch (e.g., ammonia hydroxide-hydrogen peroxide-water mixture). In some embodiments, the selective removal includes SiGe oxidation followed by a SiGeOx removal. For example, the oxidation may be provided by ozone clean and then SiGeOx is removed by an etchant such as NH₄OH. As shown in FIG. 18, the n-type source/drain regions 10NSD and the p-type source/drain regions 10PSD are covered by the SAC layer 248, the ILD layer 246 and the CESL 242.

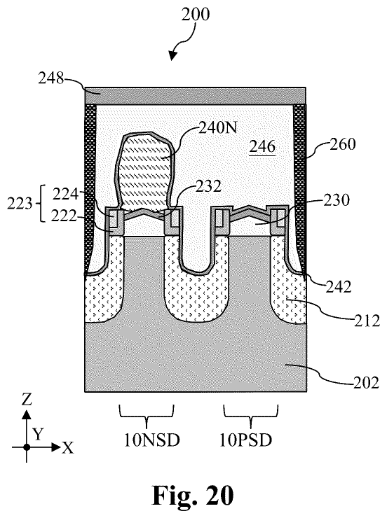

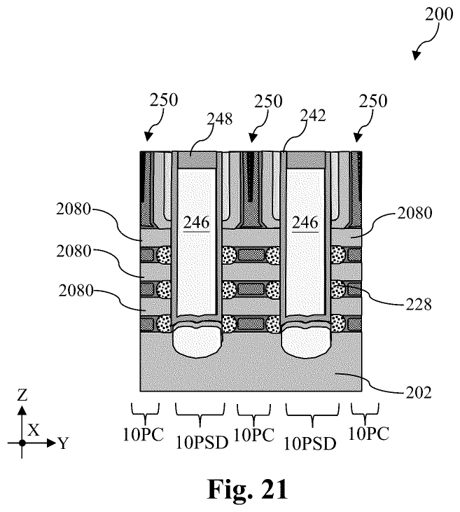

Reference is now made to FIGS. 20 and 21. After the channel members 2080 are released, gate structures 250 are formed in the channel regions to wrap around each of the channel members 2080. In the embodiments represented in FIG. 21, gate structures 250 are formed over the p-type channel regions 10PC to wrap around each of the channel members 2080. The gate structures 250 may be high-k metal gate structures that include high-k gate dielectric materials and metals. Here, a high-k dielectric material refers to a dielectric material with a dielectric constant greater than that of silicon dioxide, which is about 3.9. In various embodiments, each of the gate structures 250 includes an interfacial layer, a high-K gate dielectric layer formed over the interfacial layer, and/or a gate electrode layer formed over the high-K gate dielectric layer. The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The high-K gate dielectric layer may include a high-K dielectric layer such as hafnium oxide. Alternatively, the high-K gate dielectric layer may include other high-K dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba, Sr) TiO₃ (BST), Al₂O₃, Si₃N₄, oxynitrides (SiON), combinations thereof, or other suitable material. The high-K gate dielectric layer may be formed by ALD, physical vapor deposition (PVD), CVD, oxidation, and/or other suitable methods.

The gate electrode layer may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer may include Ti, Ag, Al, TiAlN, TaC, TaCN, TaSiN, Mn, Zr, TiN, TaN, Ru, Mo, Al, WN, Cu, W, Re, Ir, Co, Ni, other suitable metal materials or a combination thereof. In various embodiments, the gate electrode layer may be formed by ALD, PVD, CVD, e-beam evaporation, or other suitable process. In some embodiments, the gate structures 250 over p-type channel regions 10PC and n-type channel regions (not explicitly shown) may have different compositions and may be formed separately. For example, the gate structures 250 over p-type channel regions 10PC may include p-type work function metal layers while the gate structures 250 over n-type channel regions may include n-type work function metal layers. In various embodiments, a CMP process may be performed to remove excessive metal from the workpiece 200, thereby providing substantially planar top surfaces of the gate structures 250.

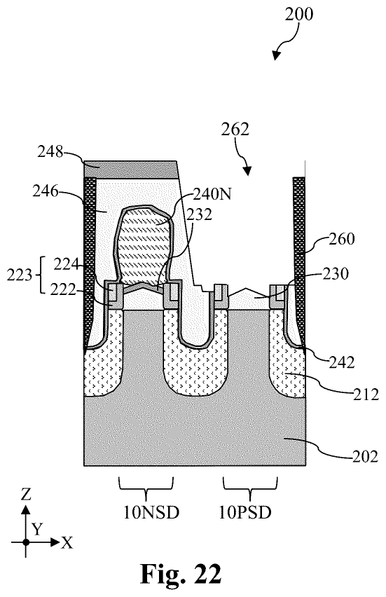

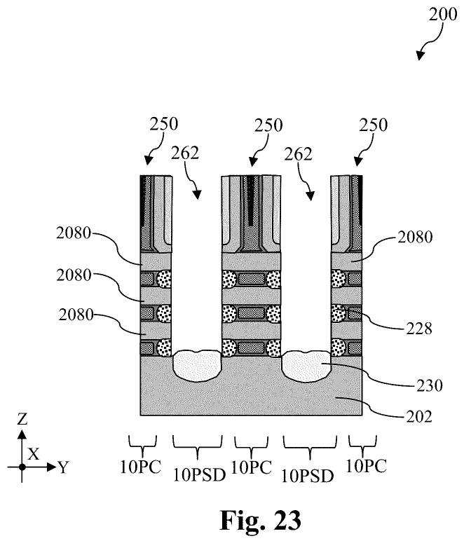

Referring to FIGS. 1, 22 and 23, method 100 includes a block 128 where p-type source/drain access openings 262 are formed over the p-type source/drain regions 10PSD. After the formation of the high-k metal gate structures 250 at block 126, photolithography and etching techniques are used to form a p-type source/drain access opening 262 over the p-type source/drain region 10PSD. As representatively shown in FIG. 22, the p-type source/drain access opening 262 is formed while the n-type source/drain features 240N are protected by the SAC layer 248, the ILD layer 246, and the CESL 242. As shown in FIG. 22, the p-type source/drain access opening 262 may expose the first spacer layer 222 and the second spacer layer 224 over the p-type source/drain regions 10PSD. Additionally, the p-type source/drain access opening 262 also exposes a sidewall and a top surface of a gate cut feature 260 adjacent the p-type source/drain region 10PSD. In some embodiments represented in FIGS. 22 and 23, in order to provide more semiconductor surfaces for the p-type source/drain features. The formation of the p-type source/drain access opening 262 also removes the isolation layer 232 over the bottom epitaxial layer 230 over the p-type source/drain region 10PSD. As shown in FIG. 23, the p-type source/drain access opening 262 not only exposes top surfaces of the bottom epitaxial layer 230 but also exposes sidewalls of released channel members 2080 that are no longer attached to sacrificial layers 206.

Referring to FIGS. 1, 24 and 25, method 100 includes a block 130 where p-type source/drain features 240P are formed over the p-type source/drain regions 10PSD. With the p-type source/drain access opening 262 exposing sidewalls of the channel members 2080 and top surfaces of the bottom epitaxial layer 230, p-type source/drain features 240P are epitaxially and selectively deposited on these exposed semiconductor surfaces. In some embodiments, each of the p-type source/drain features 240P includes one or more epitaxial layers. The one or more epitaxial layers in the p-type source/drain feature 240P may include silicon germanium (SiGe) and are in-situ doped with a p-type dopant, such as boron (B). When there are multiple epitaxial layer in the p-type source/drain feature 240P, epitaxial layers closer to the sidewalls of the channel members 2080 and top surfaces of the bottom epitaxial layer 230 include smaller p-type dopant concentrations than epitaxial layers farther away from the sidewalls of the channel layers 208 and top surfaces of the bottom epitaxial layer 230. Suitable epitaxial deposition processes to deposit the p-type source/drain features 240P may include an MBE process, a VPE process, an UHV-CVD process, an MOCVD process. In some embodiments, in order to minimize thermal impact on the high-k gate dielectric layer in the formed gate structures 250, a process temperature for depositing the p-type source/drain features 240P may be between 200° C. and about 500° C., lower than the deposition temperature for forming the n-type source/drain features 240N.

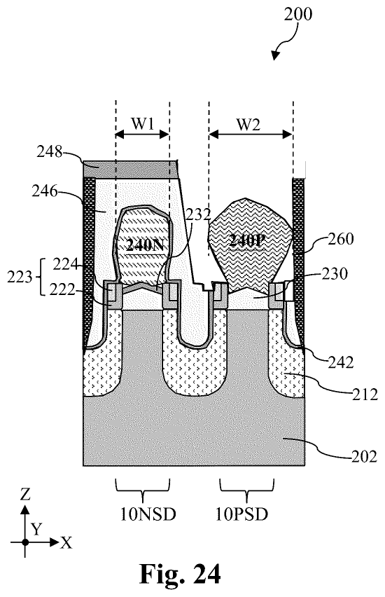

In some implementations, because the low-temperature epitaxial deposition of the p-type source/drain features 240P is less selective, the p-type source/drain feature 240P is faceted and rounded. When viewed along the channel length direction (Y direction), the p-type source/drain feature 240P is visibly wider along the X direction. Reference is now made to FIG. 24. The n-type source/drain feature 240N has a first width W1 along the X direction and the p-type source/drain feature 240P has a second width W2 along the X direction. The second width W2 is greater than the first width W1. In some instances, a ratio of the second width W2 to the first width W1 may be between about 1.2 and about 1.5. In some embodiments, the p-type source/drain feature 240P may directly contact the adjacent gate cut feature 260, which may hinder subsequent deposition of a top interlayer dielectric (ILD) layer 270 (to be described below)

Formation of the p-type source/drain features 240P after the formation of the gate structures 250 provides several benefits. For example, the p-type source/drain features 240P may more effectively compress the channel members 2080. Before the channel members 2080 are released, the sacrificial layers 206 may exert a tensile stress on the channel layers 208, preventing compressive stress to be effectively exerted to the channel layers 208. For another example, p-type source/drain features 240P are more prone to damages when the channel members 2080 are released. Forming the p-type source/drain features 240P after the release of the channel members 2080 avoid possibility of such damages.

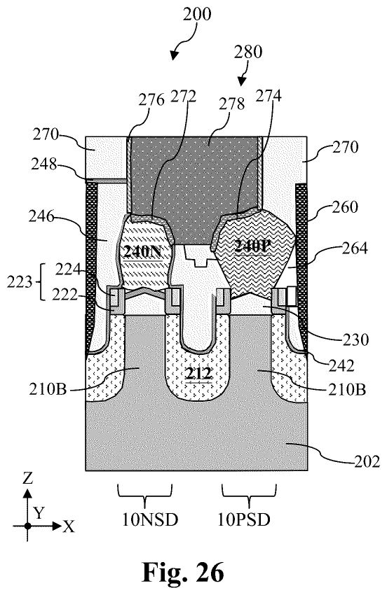

Referring to FIGS. 1, 26 and 27, method 100 includes a block 132 where source/drain contacts 280 are formed. Operations at block 132 may include deposition of a top ILD layer 270 over the p-type source/drain features 240P, formation of a source/drain contact opening to expose both a p-type source/drain feature 240P and an n-type source/drain feature 240N, formation of a first silicide layer 272 over the n-type source/drain feature 240N and a second silicide layer 274 over the p-type source/drain feature 240P, formation of a liner 276 over sidewalls of the source/drain contact opening, and deposition of a metal fill layer 278 in the source/drain contact opening. In some embodiments, the top ILD layer 270 may be similar to the ILD layer 246 in terms of composition and formation processes. Different from the ILD layer 246 that is spaced apart from the n-type source/drain feature 240N, the top ILD layer 270 is deposited directly on the p-type source/drain feature 240P. That is, surfaces of the p-type source/drain feature 240P is not lined by a counterpart of the CESL 242. Additionally, the top ILD layer 270 may be in direct contact with the first spacer layer 222 and the second spacer layer 224 over the p-type source/drain regions 10PSD. The p-type source/drain feature 240P, which may come in contact with a sidewall of the gate cut feature 260, may hinder deposition of the top ILD layer 270. As shown in FIG. 26, a gap 264 may be present between the p-type source/drain feature 240P and the gate cut feature 260.

To form the first silicide layer 272 and the second silicide layer 274, a metal precursor (e.g., titanium (Ti), cobalt (Co), or nickel (Ni)) is deposited over source/drain contact opening. An anneal is then performed to bring about silicidation between the metal precursor and the exposed n-type source/drain feature 240N and p-type source/drain feature 240P. Excess metal precursor that does not turn into the first silicide layer 272 or the second silicide layer 274 may be optionally removed using a selective wet etch. In some embodiments, the first silicide layer 272 may include titanium silicide, cobalt silicide, or nickel silicide and the second silicide layer 274 may include titanium germanosilicide, cobalt germanosilicide, or nickel germanosilicide. In another example process, a metal halide precursor (e.g., titanium tetrachloride) and a silicon-containing precursor (e.g., SiH₄) are used in a CVD process to form the first silicide layer 272 and the second silicide layer 274. After the formation of the first silicide layer 272 and the second silicide layer 274, a liner 276 is deposited over the workpiece 200 using ALD or CVD. An anisotropic dry etch process may be performed to remove the liner 276 on the first silicide layer 272 and the second silicide layer 274. In some embodiments, the liner 276 includes silicon nitride or titanium nitride. After the formation of the liner, a metal fill layer 278 is deposited over the source/drain contact opening to form the source/drain contact 280. In some instances, the metal fill layer 278 may include cobalt (Co), nickel (Ni), tungsten (W), or copper (Cu).

In one exemplary aspect, the present disclosure is directed to a method. The method includes receiving a workpiece that includes a substrate including a first region and a second region, and a first fin-shaped structure over the first region and a second fin-shaped structure over the second region, each of the first fin-shaped structure and the second fin-shaped structure comprising a plurality of channel layers interleaved by a plurality of sacrificial layers, forming a first dummy gate stack over a channel region of the first fin-shaped structure and a second dummy gate stack over a channel region of the second fin-shaped structure, forming at least one gate spacer layer over the first dummy gate stack and the second dummy gate stack, recessing a source/drain region of the first fin-shaped structure and a source/drain region of the second fin-shaped structure to form a first source/drain recess and a second source/drain recess, selectively forming a first source/drain feature over the first source/drain recess while the second source/drain recess is covered by a mask layer, removing the mask layer, depositing a first interlayer dielectric layer over the first source/drain feature and the second source/drain recess, removing the first dummy gate stack and the second dummy gate stack, releasing the plurality of channel layers in the channel region of the first fin-shaped structure and the channel region of the second fin-shaped structure to form first channel members in the first region and second channel members in the second region, forming a first gate structure to wrap around each of the first channel members and a second gate structure to wrap around each of the second channel members, after the forming of the first gate structure and the second gate structure, forming an access opening over the second source/drain recess, and forming a second source/drain feature over the access opening.

In some embodiments, the first source/drain feature includes a n-type source/drain feature and the second source/drain feature includes a p-type source/drain feature. In some implementations, the selectively forming of the first source/drain feature includes a first process temperature and the forming of the second source/drain feature includes a second process temperature smaller than the first process temperature. In some embodiments, the first process temperature is between about 500° C. and about 800° C. and the second process temperature is between about 200° C. and about 500° C. In some embodiments, the first source/drain feature includes a faceted shape and the second source/drain feature includes a rounded shape. In some instances, the method further includes before the selectively forming of the first source/drain feature, depositing a bottom epitaxial layer over the first source/drain recess and the second source/drain recess, and deposing an isolation layer over the bottom epitaxial layer. In some embodiments, the bottom epitaxial layer includes undoped silicon, undoped silicon germanium, or undoped germanium and the isolation layer includes silicon nitride. In some embodiments, the forming of the access opening includes removing the isolation layer over the second source/drain recess to expose the bottom epitaxial layer in the second region and the forming of the second source/drain feature includes forming the second source/drain feature directly on the bottom epitaxial layer. In some embodiments, after the selectively forming of the first source/drain feature, the first source/drain feature is spaced apart from the bottom epitaxial layer by the isolation layer.

In another exemplary aspect, the present disclosure is directed to a method. The method includes receiving a workpiece that includes a substrate, a first base fin and a second base fin over the substrate, and an isolation feature disposed over the substrate and between the first base fin and the second base fin, forming a first bottom epitaxial layer over the first base fin and a second bottom epitaxial layer over the second base fin, forming a first isolation layer over the first bottom epitaxial layer and a second isolation layer over the second bottom epitaxial layer, selectively forming a first source/drain feature over the first isolation layer, forming a contact etch stop layer (CESL) over the first source/drain feature and the second isolation layer, forming a first interlayer dielectric (ILD) layer over the CESL, forming an access opening through the first ILD layer, the CESL, and second isolation layer to expose the second bottom epitaxial layer, forming a second source/drain feature over the exposed second bottom epitaxial layer, and forming a second ILD layer over the second source/drain feature.

In some embodiments, the first bottom epitaxial layer and the second bottom epitaxial layer include undoped silicon, undoped silicon germanium, or undoped germanium. In some embodiments, the first source/drain feature includes silicon and an n-type dopant and the second source/drain feature includes a silicon germanium and a p-type dopant. In some embodiments, after the forming of the second ILD layer, the second ILD layer is direct contact with the second source/drain feature. In some embodiments, the selectively forming of the first source/drain feature includes a first process temperature and the forming of the second source/drain feature includes a second process temperature smaller than the first process temperature. In some instances, the first process temperature is between about 500° C. and about 800° C. and the second process temperature is between about 200° C. and about 500° C. In some embodiments, the selectively forming of the first source/drain feature includes depositing a mask layer to cover the second base fin.

In yet another exemplary aspect, the present disclosure is directed to a semiconductor structure. The semiconductor structure includes a substrate, a first base fin and a second base fin rising from the substrate, an isolation feature disposed over the substrate and between the first base fin and the second base fin, a first bottom epitaxial feature over the first base fin, a second bottom epitaxial feature over the second base fin, an isolation layer on the first bottom epitaxial feature, a first source/drain feature over the isolation layer, a second source/drain feature disposed over and in contact with the second bottom epitaxial feature, a contact etch stop layer (CESL) over the first source/drain feature and the isolation feature, a first interlayer dielectric (ILD) layer over the CESL, and a second ILD layer over and in direct contact with the second source/drain feature.

In some embodiments, the first source/drain feature includes silicon and an n-type dopant and the second source/drain feature includes silicon germanium and a p-type dopant. In some embodiments, the first bottom epitaxial feature and the second bottom epitaxial feature include undoped silicon, undoped silicon germanium, or undoped germanium. In some embodiments, the first source/drain feature includes a faceted shape and the second source/drain feature includes a rounded shape.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
receiving a workpiece comprising:
a substrate including a first region and a second region, and
a first fin-shaped structure over the first region and a second fin-shaped structure over the second region, each of the first fin-shaped structure and the second fin-shaped structure comprising a plurality of channel layers interleaved by a plurality of sacrificial layers;
forming a first dummy gate stack over a channel region of the first fin-shaped structure and a second dummy gate stack over a channel region of the second fin-shaped structure;
forming at least one gate spacer layer over the first dummy gate stack and the second dummy gate stack;
recessing a source/drain region of the first fin-shaped structure and a source/drain region of the second fin-shaped structure to form a first source/drain recess and a second source/drain recess;
selectively forming a first source/drain feature over the first source/drain recess while the second source/drain recess is covered by a mask layer;
removing the mask layer;
depositing a first interlayer dielectric layer over the first source/drain feature and the second source/drain recess;
removing the first dummy gate stack and the second dummy gate stack;
releasing the plurality of channel layers in the channel region of the first fin-shaped structure and the channel region of the second fin-shaped structure to form first channel members in the first region and second channel members in the second region;
forming a first gate structure to wrap around each of the first channel members and a second gate structure to wrap around each of the second channel members;
after the forming of the first gate structure and the second gate structure, forming an access opening over the second source/drain recess; and
forming a second source/drain feature over the access opening.

2. The method of claim 1,
wherein the first source/drain feature comprises a n-type source/drain feature,
wherein the second source/drain feature comprises a p-type source/drain feature.

3. The method of claim 1,
wherein the selectively forming of the first source/drain feature comprises a first process temperature,
wherein the forming of the second source/drain feature comprises a second process temperature smaller than the first process temperature.

4. The method of claim 3,
wherein the first process temperature is between about 500° C. and about 800° C.,
wherein the second process temperature is between about 200° C. and about 500° C.

5. The method of claim 3,
wherein the first source/drain feature comprises a faceted shape,
wherein the second source/drain feature comprises a rounded shape.

6. The method of claim 1, further comprising:
before the selectively forming of the first source/drain feature, depositing a bottom epitaxial layer over the first source/drain recess and the second source/drain recess; and
deposing an isolation layer over the bottom epitaxial layer.

7. The method of claim 6,
wherein the bottom epitaxial layer comprises undoped silicon, undoped silicon germanium, or undoped germanium,
wherein the isolation layer comprises silicon nitride.

8. The method of claim 6,
wherein the forming of the access opening comprises:
removing the isolation layer over the second source/drain recess to expose the bottom epitaxial layer in the second region,
wherein the forming of the second source/drain feature comprises forming the second source/drain feature directly on the bottom epitaxial layer.

9. The method of claim 7, wherein, after the selectively forming of the first source/drain feature, the first source/drain feature is spaced apart from the bottom epitaxial layer by the isolation layer.

10. A method, comprising:
receiving a workpiece comprising:
a substrate,
a first base fin and a second base fin over the substrate, and
an isolation feature disposed over the substrate and between the first base fin and the second base fin;
forming a first bottom epitaxial layer over the first base fin and a second bottom epitaxial layer over the second base fin;
forming a first isolation layer over the first bottom epitaxial layer and a second isolation layer over the second bottom epitaxial layer;
selectively forming a first source/drain feature over the first isolation layer;
forming a contact etch stop layer (CESL) over the first source/drain feature and the second isolation layer;
forming a first interlayer dielectric (ILD) layer over the CESL;
forming an access opening through the first ILD layer, the CESL, and second isolation layer to expose the second bottom epitaxial layer;
forming a second source/drain feature over the exposed second bottom epitaxial layer; and
forming a second ILD layer over the second source/drain feature.

11. The method of claim 10, wherein the first bottom epitaxial layer and the second bottom epitaxial layer comprise undoped silicon, undoped silicon germanium, or undoped germanium.

12. The method of claim 10,
wherein the first source/drain feature comprises silicon and an n-type dopant,
wherein the second source/drain feature comprises a silicon germanium and a p-type dopant.

13. The method of claim 10, wherein, after the forming of the second ILD layer, the second ILD layer is direct contact with the second source/drain feature.

14. The method of claim 10,
wherein the selectively forming of the first source/drain feature comprises a first process temperature,
wherein the forming of the second source/drain feature comprises a second process temperature smaller than the first process temperature.

15. The method of claim 14,
wherein the first process temperature is between about 500° C. and about 800° C.,
wherein the second process temperature is between about 200° C. and about 500° C.

16. The method of claim 10, wherein the selectively forming of the first source/drain feature comprises depositing a mask layer to cover the second base fin.

17. A semiconductor structure, comprising:
a substrate;
a first base fin and a second base fin rising from the substrate;
an isolation feature disposed over the substrate and between the first base fin and the second base fin;
a first bottom epitaxial feature over the first base fin;
a second bottom epitaxial feature over the second base fin;
an isolation layer on the first bottom epitaxial feature;
a first source/drain feature over the isolation layer;
a second source/drain feature disposed over and in contact with the second bottom epitaxial feature;
a contact etch stop layer (CESL) over the first source/drain feature and the isolation feature;
a first interlayer dielectric (ILD) layer over the CESL; and
a second ILD layer over and in direct contact with the second source/drain feature.

18. The semiconductor structure of claim 17,
wherein the first source/drain feature comprises silicon and an n-type dopant,
wherein the second source/drain feature comprises silicon germanium and a p-type dopant.

19. The semiconductor structure of claim 17, wherein the first bottom epitaxial feature and the second bottom epitaxial feature comprise undoped silicon, undoped silicon germanium, or undoped germanium.

20. The semiconductor structure of claim 17,
wherein the first source/drain feature comprises a faceted shape,
wherein the second source/drain feature comprises a rounded shape.
